(19) United States
(12) Patent Application Publication
(10) Pub. No.: US 2025/0373216 A1
(43) Pub. Date: Dec. 4, 2025

(54) TRANSCONDUCTANCE AMPLIFIER, CONTROLLER CIRCUIT, AND DC/DC CONVERTER INCLUDING CONTROLLER CIRCUIT

(71) Applicant: ROHM CO., LTD., Kyoto (JP)

(72) Inventors: Kento TAKAYANAGI, Kyoto (JP); Tsutomu ISHINO, Kyoto (JP)

(21) Appl. No.: 19/216,873

(22) Filed: May 23, 2025

(30) Foreign Application Priority Data
May 31, 2024 (JP) 2024-088552

(51) Int. Cl. H03F 3/45

(52) U.S. Cl. CPC H03F 3/45273; H03F 3/45475; H03F 2203/45054; H03F 2203/45476

(57) ABSTRACT

A transconductance amplifier that generates an output voltage by amplifying a difference between an input voltage and a reference voltage, includes: a differential amplifier circuit including an input differential pair configured to receive the input voltage and the reference voltage and operate according to a tail current, and an output circuit provided as an active load of the input differential pair to generate the output voltage; and a current control circuit configured to control the tail current, wherein the current control circuit is configured to increase the tail current when a current supply condition is satisfied, and the current supply condition is that the input voltage falls below a first threshold voltage which is equal to or lower than the reference voltage, or that the input voltage exceeds a second threshold voltage which is equal to or higher than the reference voltage.

### CROSS-REFERENCE TO RELATED APPLICATION

The present invention claims priority under 35 U.S.C. § 119 to Japanese Patent Application No. 2024-088552, filed on May 31, 2024, the entire contents of which are incorporated herein by reference.

### TECHNICAL FIELD

The present disclosure relates to a transconductance amplifier, a controller circuit, and a DC/DC converter including the controller circuit.

### BACKGROUND

Various DC/DC converters use an error amplifier that receives a feedback voltage to bring an output voltage closer to a desired voltage. In the related art, there is disclosed a step-up DC/DC converter including an error amplifier that amplifies an error between a feedback voltage corresponding to an output voltage and a reference voltage. In the related art, there is disclosed a step-down DC/DC converter including an error amplifier that generates an error signal corresponding to a difference between a feedback voltage corresponding to an output voltage and a reference voltage.

### BRIEF DESCRIPTION OF DRAWINGS

The accompanying drawings, which are incorporated in and constitute a part of the specification, illustrate embodiments of the present disclosure.

FIG. 1 is a block diagram of a DC/DC converter according to a first embodiment.

FIG. 2 is a block diagram of a first error amplifier according to the first embodiment.

FIG. 3 is a circuit diagram of a first current control circuit according to the first embodiment.

FIG. 4 is a circuit diagram of a second current control circuit according to the first embodiment.

FIG. 5 is a circuit diagram of a differential amplifier circuit according to the first embodiment.

FIG. 6 is a diagram showing changes in a first output current supplied by the first current control circuit and a second output current supplied by the second current control circuit with respect to a feedback voltage.

FIG. 7 is a timing chart showing an example of an output voltage of an error amplifier circuit according to the first embodiment, an output voltage of an error amplifier circuit according to a first comparative technique, and an output voltage of an error amplifier circuit according to a second comparative technique.

FIG. 8 is a diagram showing the first output current and the second output current during a period T1 shown in FIG. 7.

FIG. 9 is a diagram showing the first output current and the second output current during a period T2 shown in FIG. 7.

FIG. 10 is a circuit diagram of a first current control circuit according to a second embodiment.

FIG. 11 is a circuit diagram of a second current control circuit according to the second embodiment.

FIG. 12 is a diagram showing a voltage divider circuit according to a third modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview

The overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments (examples or modifications) disclosed herein.

A transconductance amplifier according to one embodiment generates an output voltage by amplifying a difference between an input voltage and a reference voltage. The transconductance amplifier includes: a differential amplifier circuit including an input differential pair that receives the input voltage and the reference voltage and operates according to a tail current, and an output circuit that generates the output voltage and is provided as an active load of the input differential pair; and a current control circuit that controls the tail current. The current control circuit is configured to increase the tail current when a current supply condition is satisfied. The current supply condition is that the input voltage falls below a first threshold voltage which is equal to or lower than the reference voltage, or that the input voltage exceeds a second threshold voltage which is equal to or higher than the reference voltage.

With this configuration, when the input voltage falls below the first threshold voltage or exceeds the second threshold voltage, the tail current of the differential amplifier circuit becomes large. As a result, it is possible to appropriately control transconductance (gm) of the transconductance amplifier according to the input voltage.

In one embodiment, the current control circuit may include a differential circuit to which the input voltage and the reference voltage are input, a current mirror circuit provided as an active load of the differential circuit, and a current supply circuit provided as an active load of the current mirror circuit. The current mirror circuit may supply a current corresponding to a differential current of the differential circuit to the current supply circuit when the current supply condition is satisfied. The current supply circuit may contribute an output current, which corresponds to the current supplied from the current mirror circuit, to the tail current.

In one embodiment, the differential circuit may be configured so that the first threshold voltage is a voltage lower by a first offset voltage than the reference voltage, or the second threshold voltage is a voltage higher by a second offset voltage than the reference voltage.

In one embodiment, the differential circuit may include one or more first transistors to which the input voltage is input, and one or more second transistors to which the reference voltage is input. The first transistor and the second transistor may form a differential pair and may be of a same type. The number of first transistors may be different from the number of second transistors.

In one embodiment, the differential circuit may include a first transistor to which the input voltage is input, and a second transistor which forms a differential pair with the first transistor. The second transistor may receive the first threshold voltage or the second threshold voltage.

In one embodiment, when the current mirror circuit is a first current mirror circuit, the current supply circuit may include a second current mirror circuit provided as an active load of the first current mirror circuit, and a third current mirror circuit provided as an active load of the second current mirror circuit. When the current supply condition is satisfied, the second current mirror circuit may be provided to copy a current, which corresponds to a differential current of the differential circuit and is supplied from the first current mirror circuit. The third current mirror circuit may be provided to copy the current copied by the second current mirror circuit to generate the output current.

In one embodiment, the current control circuit may include a first current control circuit and a second current control circuit. The first current control circuit may be configured to increase the tail current when the input voltage falls below the first threshold voltage. The second current control circuit may be configured to increase the tail current when the input voltage exceeds the second threshold voltage.

In one embodiment, the first current control circuit may include a first differential circuit to which the input voltage and the reference voltage are input, a first current mirror circuit provided as an active load of the first differential circuit, and a first current supply circuit provided as an active load of the first current mirror circuit. The second current control circuit may include a second differential circuit to which the input voltage and the reference voltage are input, a fourth current mirror circuit provided as an active load of the second differential circuit, and a second current supply circuit provided as an active load of the fourth current mirror circuit. The first current mirror circuit may supply a current corresponding to a differential current of the first differential circuit to the first current supply circuit when the input voltage falls below the first threshold voltage. The first current supply circuit may contribute a first output current, which corresponds to the current supplied from the first current mirror circuit, to the tail current. The fourth current mirror circuit may supply a current corresponding to a differential current of the second differential circuit to the second current supply circuit when the input voltage exceeds the second threshold voltage. The second current supply circuit may contribute a second output current, which corresponds to the current supplied from the fourth current mirror circuit, to the tail current.

In one embodiment, the first differential circuit may be configured so that the first threshold voltage is a voltage lower by a first offset voltage than the reference voltage. The second differential circuit may be configured so that the second threshold voltage is a voltage higher by a second offset voltage than the reference voltage.

In one embodiment, the output circuit may be configured as a cascode current mirror circuit.

A controller circuit for a DC/DC converter according to one embodiment may include the above-described transconductance amplifier. The input voltage may be a feedback voltage of an output voltage of the DC/DC converter.

In one embodiment, the controller circuit may be integrated on a single semiconductor chip.

A DC/DC converter according to one embodiment may include the above-described controller circuit.

### EMBODIMENTS

Preferred embodiments will now be described with reference to the drawings. Like or equivalent components, members, and processes illustrated in each drawing are given like reference numerals and a repeated description thereof will be properly omitted. Further, the embodiments are presented by way of example only and are not intended to limit the present disclosure and invention, and any features or combination thereof described in the embodiments may not necessarily be essential to the present disclosure and invention.

In the present disclosure, the expression “a member A is connected to a member B” includes not only a case where the member A and the member B are physically directly connected to each other, but also a case where the member A and the member B are indirectly connected to each other via any other member that does not substantially affect an electrical connection state between the members A and B or does not impair functions and effects achieved by combinations of the members A and B.

Similarly, the expression “a member C is connected (installed) between a member A and a member B” includes to not only a case where the member A and the member C or the member B and the member C are directly connected to each other, but also a case where the member A and the member C or the member B and the member C are indirectly connected to each other via any other member that does not substantially affect an electrical connection state between the members A and C or the members B and C or does not impair functions and effects achieved by combinations of the members A and C or the members B and C.

Further, in the present disclosure, symbols attached to electrical signals such as voltage signals and current signals, or circuit elements such as resistors, capacitors, and inductors, represent respective voltage values, current values, or circuit constants (resistance, capacitance, and inductance) as necessary.

Further, in the present disclosure, the term “integrated” includes a case where all of constituent elements of a circuit are formed on a semiconductor substrate and a case where main constituent elements of the circuit are integrated, and some resistors, capacitors, and the like may be provided outside the semiconductor substrate for adjusting circuit constants.

### First Embodiment

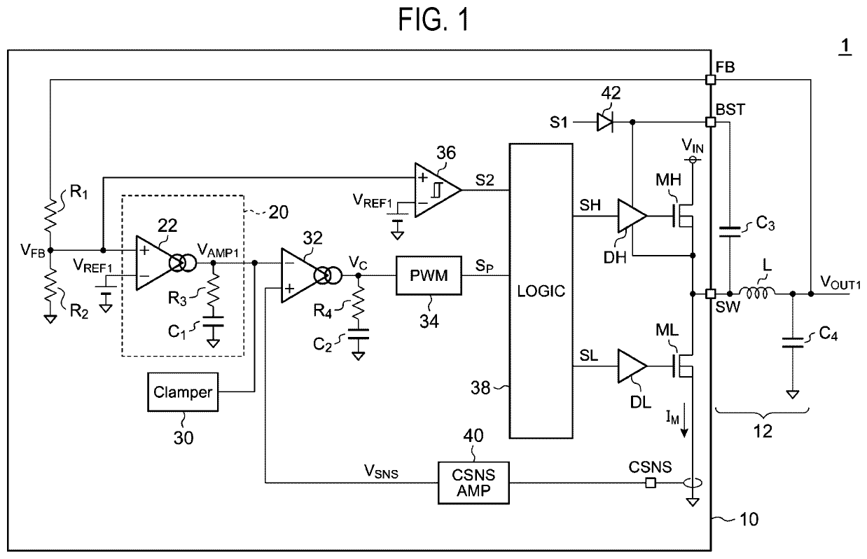

FIG. 1 is a block diagram of a DC/DC converter 1 according to a first embodiment. The DC/DC converter 1 generates an output voltage V_{OUT1} according to an input voltage V_{IN}. The DC/DC converter 1 according to this embodiment includes a controller circuit 10 and a peripheral circuit 12.

The controller circuit 10 is a circuit for controlling an operation of the DC/DC converter 1, and may be integrated on a single semiconductor chip. The controller circuit 10 according to this embodiment includes a first error amplifier 22, a clamp circuit 30, a second error amplifier 32, a pulse generator 34, a comparator 36, a logic circuit 38, a sense amplifier circuit 40, a buffer circuit 42, resistors R₁ to R₄, capacitors C₁ and C₂, a high-side driver DH, a low-side driver DL, a high-side transistor MH, a low-side transistor ML, a feedback pin FB, a bootstrap pin BST, a switching pin SW, and a sensing pin CSNS.

The output voltage V_{OUT1} of the DC/DC converter 1 is fed back to the feedback pin FB. The output voltage V_{OUT1} is divided by the resistors R₁ and R₂ to generate a feedback voltage V_{FB} of the output voltage V_{OUT1}. Here, a relationship of V_{FB}=V_{OUT1}×R₂/(R₁+R₂) is established. The feedback voltage V_{FB} is input to a non-inverting input terminal of the first error amplifier 22 and a non-inverting input terminal of the comparator 36.

The first error amplifier 22 is a transconductance amplifier, and generates an output voltage V_{AMP1} by amplifying a difference between the input voltage and a reference voltage V_{REF1}. Specifically, the first error amplifier 22 generates the output voltage V_{AMP1} by amplifying a difference between the feedback voltage V_{FB} (the input voltage) input to its non-inverting input terminal and the reference voltage V_{REF1} input to its inverting input terminal. A detailed configuration of the first error amplifier 22 will be described later.

The resistor R₃ and the capacitor C₁ for phase compensation are serially connected to each other. One end of the resistor R₃ on the opposite side to the capacitor C₁ is connected to an output terminal of the first error amplifier 22. One end of the capacitor C₁ on the opposite side to the resistor R₃ is connected to the ground. Here, the first error amplifier 22, the resistor R₃, and the capacitor C₁ constitute an error amplifier circuit 20. The output voltage V_{AMP1} of the first error amplifier 22 is generated as the output voltage of the error amplifier circuit 20 after being subjected to the phase compensation by the resistor R₃ and the capacitor C₁. The clamp circuit 30 clamps the output voltage V_{AMP1}.

When a fluctuation occurs in a load (not shown) of the DC/DC converter 1, a fluctuation occurs in an input signal (the input voltage V_{FB}) of the error amplifier circuit 20. A response speed of the error amplifier circuit 20 to the fluctuation of the input signal is limited by the product of gm of the first error amplifier 22 and a capacitance value of the capacitor C₁, that is, gm×C₁. The higher this product, the faster the response speed of the error amplifier circuit 20, making it possible to respond quickly to the load fluctuation. Therefore, the higher the gm of the first error amplifier 22, the faster the response speed of the error amplifier circuit 20.

The second error amplifier 32 generates a voltage V_{C} by amplifying a difference between a signal V_{SNS} from the sense amplifier circuit 40, which is input to the non-inverting input terminal of the second error amplifier 32, and the output voltage V_{AMP1} input to the inverting input terminal thereof. The resistor R₄ and capacitor C₂ for phase compensation are serially connected to each other. One end of the resistor R₄ on the opposite side to the capacitor C₂ is connected to an output terminal of the second error amplifier 32. One end of the capacitor C₂ on the opposite side to the resistor R₄ is connected to the ground.

The pulse generator 34 generates a pulse signal S_{P} for controlling a duty ratio based on the voltage V_{C}. The pulse generator 34 may include a comparator that compares a periodic signal of a sawtooth wave or a ramp wave with the voltage V_{C}. Further, the pulse generator 34 may include a clock signal generator for generating a sawtooth wave or a ramp wave.

The comparator 36 generates a signal S₂ according to a result of comparison between the feedback voltage V_{FB} input to its non-inverting input terminal with the reference voltage V_{REF1}. This signal S₂ may be used by the logic circuit 38 at light load.

The logic circuit 38 generates a high-side control signal SH and a low-side control signal SL based on the pulse signal S_{P}. The high-side driver DH drives the high-side transistor MH based on the high-side control signal SH. The low-side driver DL drives the low-side transistor ML based on the low-side control signal SL. In response to the driving of the high-side transistor MH and the low-side transistor ML, the output voltage V_{OUT1} according to the input voltage V_{IN} is generated.

Each of the high-side transistor MH and the low-side transistor ML is constituted with an N-channel MOS (Metal Oxide Semiconductor) transistor. A source of the high-side transistor MH is connected to the switching pin SW, and the input voltage V_{IN} is supplied to a drain of the high-side transistor MH. A source of the low-side transistor ML is connected to the ground, and a drain of the low-side transistor ML is connected to the switching pin SW.

The sense amplifier circuit 40 detects a current I_{M} flowing through the low-side transistor ML and generates the signal V_{SNS} according to the detection result.

The buffer circuit 42 receives a signal S1. An output terminal of the buffer circuit 42 is connected to the high-side driver DH and the bootstrap pin BST.

The peripheral circuit 12 includes an inductor L and capacitors C₃ and C₄. One end of the capacitor C₃ is connected to the bootstrap pin BST, and the other end of the capacitor C₃ is connected to the switching pin SW. One end of the inductor L is connected to the switching pin SW, and the other end of the inductor L is connected to the feedback pin FB. The output voltage V_{OUT1} is output from the other end of the inductor L. The capacitor C₄ is provided between the other end of the inductor L1 and the ground.

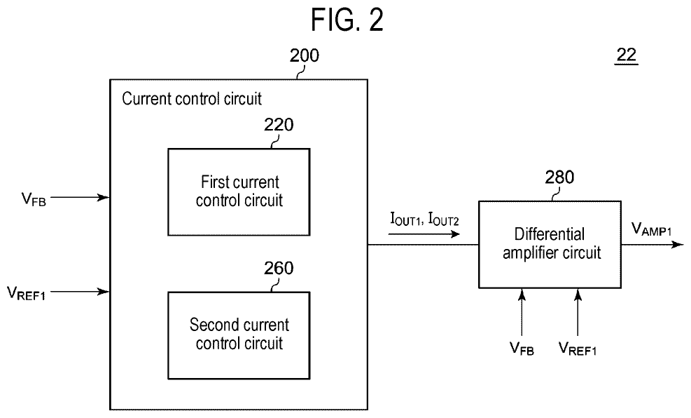

FIG. 2 is a block diagram of the first error amplifier 22 according to this embodiment. The first error amplifier 22 according to this embodiment includes a current control circuit 200 and a differential amplifier circuit 280.

The differential amplifier circuit 280 generates the output voltage V_{AMP1} by amplifying the difference between the feedback voltage V_{FB} and the reference voltage V_{REF1}. The differential amplifier circuit 280 includes an input differential pair that operates according to a tail current Iₜₐᵢₗ (not shown in FIG. 2), and the like. The gm of the first error amplifier 22 is adjusted by controlling a magnitude of this tail current Iₜₐᵢₗ.

The current control circuit 200 controls the tail current Iₜₐᵢₗ of the input differential pair of the differential amplifier circuit 280. Specifically, the current control circuit 200 is configured to increase the tail current Iₜₐᵢₗ when a current supply condition is satisfied. The current supply condition is that the feedback voltage V_{FB} falls below a first threshold voltage Vₜₕ₁ which is equal to or lower than the reference voltage V_{REF1}, or that the feedback voltage V_{FB} exceeds a second threshold voltage Vₜₕ₂ which is equal to or higher than the reference voltage V_{REF1}.

The current control circuit 200 according to this embodiment includes a first current control circuit 220 and a second current control circuit 260. The first current control circuit 220 is configured to increase the tail current Iₜₐᵢₗ of the input differential pair of the differential amplifier circuit 280 when the feedback voltage V_{FB} falls below the first threshold voltage Vₜₕ₁. The second current control circuit 260 is configured to increase the tail current Iₜₐᵢₗ of the input differential pair of the differential amplifier circuit 280 when the feedback voltage V_{FB} exceeds the second threshold voltage Vₜₕ₂.

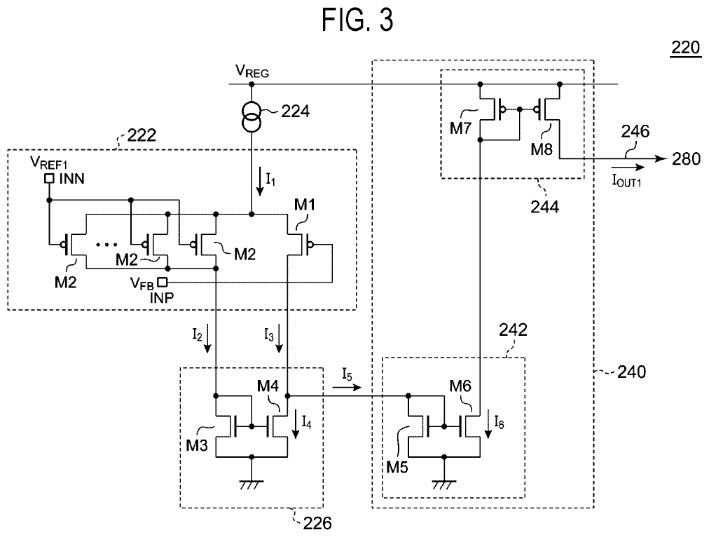

FIG. 3 is a circuit diagram of the first current control circuit 220 according to this embodiment. The first current control circuit 220 according to this embodiment includes a first differential circuit 222, a current source 224, a first current mirror circuit 226, and a first current supply circuit 240. A voltage V_{REG} shown in FIG. 3 is a voltage generated based on the input voltage V_{IN} using an LDO (Low Dropout) (not shown).

The first differential circuit 222 receives the feedback voltage V_{FB} and the reference voltage V_{REF1}. The first differential circuit 222 generates differential currents I₂ and I₃ according to a current I₁ supplied from the current source 224. The first differential circuit 222 according to this embodiment is configured so that the first threshold voltage Vₜₕ₁ is a voltage lower by an offset voltage V_{OFF1} (>0) than the reference voltage V_{REF1}. Therefore, Vₜₕ₁=V_{REF1}−V_{OFF1}. A magnitude of the offset voltage V_{OFF1} may be set appropriately depending on a magnitude of fluctuation of the feedback voltage V_{FB} when a load changes.

The first differential circuit 222 includes a transistor M1 and a plurality of transistors M2, each of which forms a differential pair with the transistor M1. In the first differential circuit 222, the transistor M1 is a first transistor to which the feedback voltage V_{FB} is input, and the transistor M2 is a second transistor to which the reference voltage V_{REF1} is input.

The transistor M1 and the plurality of transistors M2 are of a same type, and specifically, each transistor is configured as a P-channel MOS transistor. The number of transistors M1 is different from the number of transistors M2. Hereinafter, when the number of transistors forming differential pairs on one side is different from the number of transistors forming differential pairs on the other side, this is also referred to as “the number of multi being different.” Specifically, the number of transistors M1 is one, and the number of transistors M2 is n (n is an integer equal to or greater than 2).

A gate of the transistor M1 is connected to a non-inverting input terminal INP to which the feedback voltage V_{FB} is supplied. Therefore, the feedback voltage V_{FB} is input to the gate of the transistor M1. A source of the transistor M1 is connected to the current source 224 in common with the source of each of the plurality of transistors M2. A gate of each of the plurality of transistors M2 is connected to an inverting input terminal INN to which the reference voltage V_{REF1} is supplied. Thus, the reference voltage V_{REF1} is input to the gate of each of the plurality of transistors M2.

The first current mirror circuit 226 is provided as an active load of the first differential circuit 222. The first current mirror circuit 226 according to this embodiment is configured to supply a current I₅ corresponding to the differential currents I₂ and I₃ of the first differential circuit 222 to the first current supply circuit 240 when the feedback voltage V_{FB} falls below the first threshold voltage Vₜₕ₁. Here, I₂ is the sum of drain currents flowing through the n transistors M2, and I₃ is a drain current of the transistor M1. The current I₅ is a drain current of a transistor M5.

The first current mirror circuit 226 includes transistors M3 and M4, each of which is configured as an N-channel MOS transistor. A gate of the transistor M3 is connected to a drain of the transistor M3 in common with a gate of the transistor M4. The drain of the transistor M3 is connected to a drain of each of the plurality of transistors M2. A source of the transistor M3 is connected to the ground in common with a source of the transistor M4. A drain of the transistor M4 is connected to the drain of the transistor M1.

The first current supply circuit 240 is provided as an active load of the first current mirror circuit 226. The first current supply circuit 240 is configured to contribute a first output current I_{OUT1}, which corresponds to the current I₅ supplied from the first current mirror circuit 226, to the tail current Iₜₐᵢₗ of the differential amplifier circuit 280. The first current supply circuit 240 according to this embodiment includes a second current mirror circuit 242 and a third current mirror circuit 244.

The second current mirror circuit 242 is provided as an active load of the first current mirror circuit 226. When the feedback voltage V_{FB} falls below the first threshold voltage Vₜₕ₁, the second current mirror circuit 242 is provided to copy the current I₅, which corresponds to the differential currents I₂ and I₃ of the first differential circuit 222 and is supplied from the first current mirror circuit 226. The second current mirror circuit 242 includes transistors M5 and M6, each of which is configured as an N-channel MOS transistor.

A gate of the transistor M5 is connected to a drain of the transistor M5 in common with a gate of the transistor M6. The drain of the transistor M5 is connected to the drain of the transistor M4. A source of the transistor M5 is connected to the ground in common with a source of the transistor M6. A current I₆, which is a copy of the current I₅ supplied from the first current mirror circuit 226, flows through the transistor M6.

The third current mirror circuit 244 is provided as an active load of the second current mirror circuit 242. The third current mirror circuit 244 is provided to copy the current I₆ copied by the second current mirror circuit 242 to generate the first output current I_{OUT1}. The third current mirror circuit 244 includes transistors M7 and M8, each of which is configured as a P-channel MOS transistor.

A gate of the transistor M7 is connected to a drain of the transistor M7 in common with a gate of the transistor M8. A drain of the transistor M7 is connected to the drain of the transistor M6. A drain of the transistor M8 is connected to the differential amplifier circuit 280. The first output current I_{OUT1}, which is a copy of the current I₆ flowing through the transistor M6, flows through the transistor M8. This first output current I_{OUT1} contributes to the tail current Iₜₐᵢₗ of the differential amplifier circuit 280 via a current supply line 246 connected to the drain of the transistor M8.

The configuration of the first current control circuit 220 according to this embodiment has been described above. Hereinafter, the operation of the first current control circuit 220 according to this embodiment will be described.

In a case of Vₜₕ₁=V_{REF1}−V_{OFF1}≤V_{FB}, a relationship of I₂=I₃=I₄ is established. The current I₄ is a current flowing through the transistor M4. The offset voltage V_{OFF1} occurs because the number of transistors M2 is greater than the number of transistors M1. At this time, no current is supplied to the second current mirror circuit 242 (I₅=0).

When a fluctuation occurs in the load of the DC/DC converter 1 and the feedback voltage V_{FB} drops so that Vₜₕ₁>V_{FB}, a relationship of I₂<I₃ is established. At this time, since the current I₂ is copied in the first current mirror circuit 226, a relationship of I₂=I₄ is established, and the current of I₅ (=I₃−I₄) is supplied to the second current mirror circuit 242. This current I₅ is copied to generate the current I₆, and the first output current I_{OUT1} which is a copy of the current I₆ is generated. This first output current I_{OUT1} contributes to the tail current Iₜₐᵢₗ of the differential amplifier circuit 280.

In a case of Vₜₕ₁>V_{FB}, I_{OUT1} increases as V_{FB} decreases, but the first output current I_{OUT1} is generated based on the current I₁ supplied from the current source 224. Therefore, an upper limit of O_{OUT1} is Iₘₐₓ₁ according to I₁.

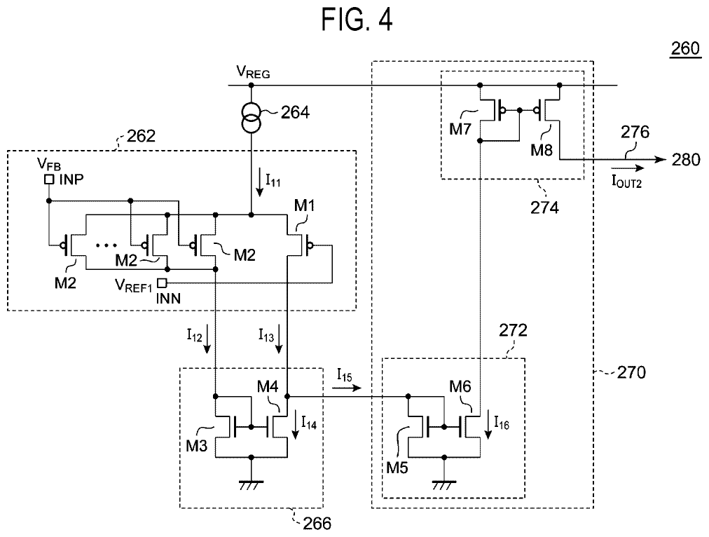

FIG. 4 is a circuit diagram of the second current control circuit 260 according to this embodiment. The second current control circuit 260 includes a second differential circuit 262, a current source 264, a fourth current mirror circuit 266, and a second current supply circuit 270. The current source 264, the fourth current mirror circuit 266, and the second current supply circuit 270 may have substantially the same configuration as the current source 224, the first current mirror circuit 226, and the first current supply circuit 240 of the first current control circuit 220, respectively.

The second differential circuit 262 receives the feedback voltage V_{FB} and the reference voltage V_{REF1}. The second differential circuit 262 is configured so that the second threshold voltage Vₜₕ₂ is higher by a second offset voltage V_{OFF2} (>0) than the reference voltage V_{REF1}. Therefore, a relationship of Vₜₕ₂=V_{REF1}+V_{OFF2} is established. A magnitude of the second offset voltage V_{OFF2} may be set appropriately depending on a magnitude of fluctuation of the feedback voltage V_{FB} when the load fluctuates.

The second differential circuit 262 is different from the first differential circuit 222 of the first current control circuit 220 in that the non-inverting input terminal INP and the inverting input terminal INN are reversed. The second current control circuit 260 may have substantially the same configuration as the first current control circuit 220, except for the non-inverting input terminal INP and the inverting input terminal INN. Therefore, the second offset voltage V_{OFF2} may be the same as the first offset voltage V_{OFF1} (V_{OFF2}=V_{OFF1}). In the second differential circuit 262, the transistor M2 is the first transistor to which the feedback voltage V_{FB} is input, and the transistor M1 is the second transistor to which the reference voltage V_{REF1} is input.

The fourth current mirror circuit 266 is provided as an active load of the second differential circuit 262. When the feedback voltage V_{FB} exceeds the second threshold voltage Vₜₕ₂, the fourth current mirror circuit 266 is configured to supply a current I₁₅, which corresponds to differential currents I₁₂ and I₁₃ of the second differential circuit 262, to the second current supply circuit 270.

The second current supply circuit 270 is provided as an active load of the fourth current mirror circuit 266. The second current supply circuit 270 is configured to contribute a second output current I_{OUT2}, which corresponds to the current I₁₅ supplied from the fourth current mirror circuit 266, to the tail current Iₜₐᵢₗ of the differential amplifier circuit 280.

The second current supply circuit 270 includes a fifth current mirror circuit 272 provided as an active load of the fourth current mirror circuit 266, and a sixth current mirror circuit 274 provided as an active load of the fifth current mirror circuit 272. When the feedback voltage V_{FB} exceeds the second threshold voltage Vₜₕ₂, the fifth current mirror circuit 272 is provided to copy the current I₁₅, which corresponds to the differential currents I₁₂ and I₁₃ of the second differential circuit 262 and is supplied from the fourth current mirror circuit 266. The sixth current mirror circuit 274 is provided to copy a current I₁₆ copied by the fifth current mirror circuit 272 to generate the second output current I_{OUT2}.

An operation of the second current control circuit 260 will be described below. In a case of Vₜₕ₂=V_{REF1}+V_{OFF2}>V_{FB}, a relationship of I₁₂=I₁₃=I₁₄ is established. The current I₁₂ is a sum of drain currents of the n transistors M2, the current I₁₃ is a drain current of the transistor M1, and the current I₁₄ is a current flowing through the transistor M4. At this time, no current is supplied to the second current supply circuit 270 (I₁₅=0).

When a load fluctuation occurs and the feedback voltage V_{FB} rises so that Vₜₕ₂<V_{FB}, I₁₂ becomes less than I₁₃. At this time, since the current I₁₂ is copied in the fourth current mirror circuit 266, I₁₂=I₁₄. The current I₁₄ is a current flowing through the transistor M4. The current I₁₅ (=I₁₃−I₁₄) is supplied to the second current supply circuit 270. This current I₁₅ is copied to generate the current I₁₆, and the second output current I_{OUT2} is generated by copying the current I₁₆. This second output current I_{OUT2} contributes to the tail current Iₜₐᵢₗ of the differential amplifier circuit 280 via a current supply line 276 connected to the drain of the transistor M8.

In a case in which Vₜₕ₂<V_{FB}, the larger V_{FB} becomes, the larger I_{OUT2} becomes, but the second output current I_{OUT2} is generated based on a current I₁₁ supplied from the current source 264. Therefore, an upper limit of I_{OUT2} is Iₘₐₓ₂ according to I₁₁. In this embodiment, Iₘₐₓ₂=Iₘₐₓ₁.

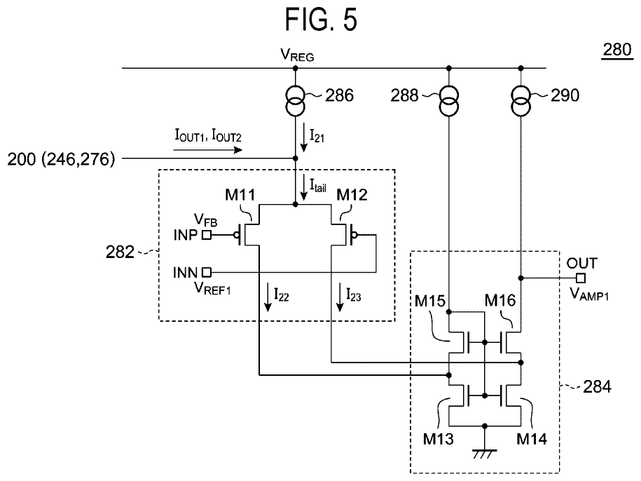

FIG. 5 is a circuit diagram of the differential amplifier circuit 280 according to this embodiment. The differential amplifier circuit 280 includes an input differential pair 282, an output circuit 284, and current sources 286, 288, and 290.

The input differential pair 282 receives the feedback voltage V_{FB} and the reference voltage V_{REF1} and operates according to the tail current Iₜₐᵢₗ. The input differential pair 282 includes transistors M11 and M12, each of which is configured as a P-channel MOS transistor. A gate of the transistor M11 is connected to the non-inverting input terminal INP, and a gate of the transistor M12 is connected to the inverting input terminal INN. A source of the transistor M11 is connected to the current source 286 and the current control circuit 200 (specifically, the current supply lines 246 and 276) in common with a source of the transistor M12.

The output circuit 284 is provided as an active load of the input differential pair 282, and generates the output voltage V_{AMP1} according to differential currents I₂₂ and I₂₃ of the input differential pair 282. The output circuit 284 according to this embodiment is configured as a cascode current mirror circuit. The output circuit 284 includes transistors M13 to M16, each of which is configured as an N-channel MOS transistor.

A gate of the transistor M13 is connected to a drain of the transistor M15 in common with a gate of each of the transistors M14 to M16. A source of the transistor M13 is connected to the ground in common with a source of the transistor M14. A drain of the transistor M13 is connected to the drain of the transistor M11 in common with a source of the transistor M15. A drain of the transistor M14 is connected to the drain of the transistor M12 in common with a source of the transistor M16. A drain of the transistor M15 is connected to the current source 288. A drain of the transistor M16 is connected to the current source 290 and an output terminal OUT. The output voltage V_{AMP1} is output from the output terminal OUT.

The gm changes according to the tail current Iₜₐᵢₗ supplied to the input differential pair 282. Specifically, the larger the tail current Iₜₐᵢₗ, the larger the gm becomes. As described above, when the feedback voltage V_{FB} falls below the first threshold voltage Vₜₕ₁, the first output current Iouri contributes to the tail current Iₜₐᵢₗ. In addition, when the feedback voltage V_{FB} exceeds the second threshold voltage Vₜₕ₂, the second output current I_{OUT2} contributes to the tail current Iₜₐᵢₗ. As a result, when the feedback voltage V_{FB} falls outside the range of Vₜₕ₁≤V_{FB}≤Vₜₕ₂, the tail current Iₜₐᵢₗ becomes larger than a current I₂₁ supplied from the current source 286. This increases the gm, which makes it possible for the error amplifier circuit 20 to respond quickly to the load fluctuation.

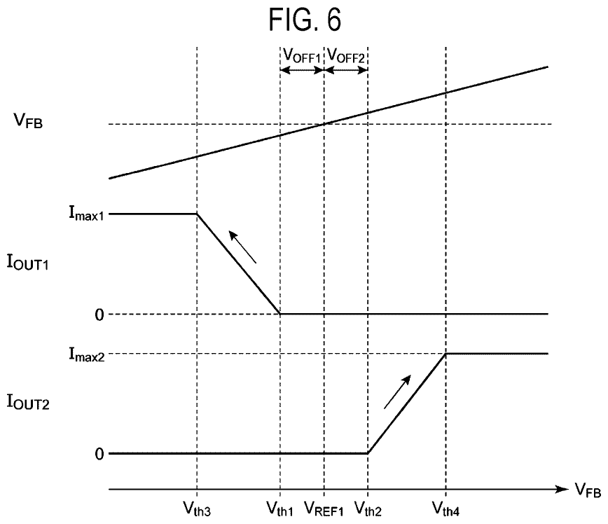

FIG. 6 is a diagram showing changes in the first output current I_{OUT1} supplied by the first current control circuit 220 and the second output current I_{OUT2} supplied by the second current control circuit 260 with respect to the feedback voltage V_{FB}. In FIG. 6, the horizontal axis represents the feedback voltage V_{FB}.

As shown in FIG. 6, the first output current I_{OUT1} is 0 for Vₜₕ₁≤V_{FB}. In the case of Vₜₕ₁>V_{FB}, the first output current I_{OUT1} increases with a decrease in the feedback voltage V_{FB}. Here, when a third threshold voltage Vₜₕ₃ lower than the first threshold voltage Vₜₕ₁ is defined, the first output current I_{OUT1} becomes a constant value at Iₘₐₓ₁ in a case of Vₜₕ₃>V_{FB}. The second output current I_{OUT2} is 0 for Vₜₕ₂>V_{FB}. In the case of Vₜₕ₂<V_{FB}, the second output current I_{OUT2} increases with an increase in the feedback voltage V_{FB}. Here, when a fourth threshold voltage Vₜₕ₄ lower than the second threshold voltage Vₜₕ₂ is defined, the second output current I_{OUT2} becomes a constant value at Iₘₐₓ₂ in a case of Vₜₕ₄<V_{FB}.

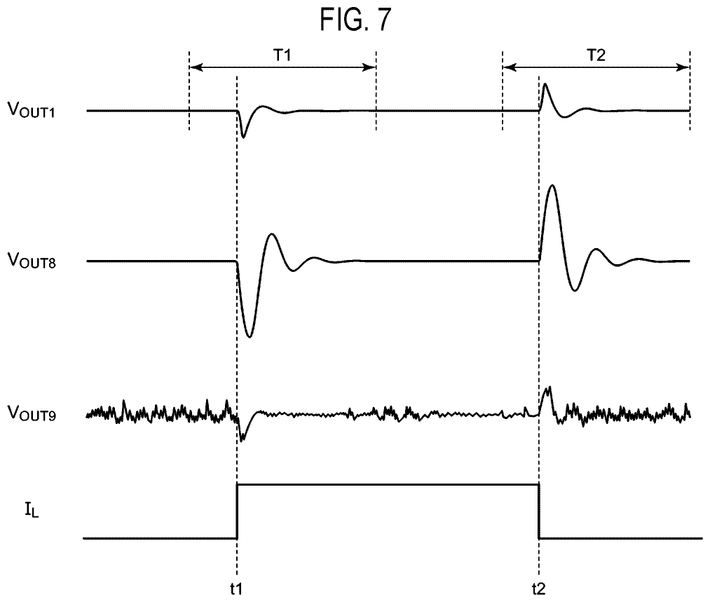

FIG. 7 is a timing chart showing an example of the output voltage V_{OUT1} of the error amplifier circuit 20 according to this embodiment, an output voltage V_{OUT8} of an error amplifier circuit according to a first comparative technique, and an output voltage V_{OUT9} of an error amplifier circuit according to a second comparative technique. A current I_{L} shown at the bottom of FIG. 7 is an output current flowing through the inductor L of the DC/DC converter 1.

The error amplifier circuit according to the first comparative technique is a circuit in which the first error amplifier 22 according to this embodiment is replaced with an error amplifier according to the first comparative technique. In addition, the error amplifier circuit according to the second comparative technique is a circuit in which the first error amplifier 22 according to this embodiment is replaced with an error amplifier according to the second comparative technique. The error amplifier according to the first comparative technique is different from the first error amplifier 22 according to this embodiment in that the former does not include the current control circuit 200. In addition, the error amplifier according to the second comparative technique is an error amplifier with a larger gm than the error amplifier according to the first comparative technique.

At timing t1 and timing t2, a load fluctuation occurs, and the current I_{L} changes in response to the fluctuation. In response to this, each of the output voltages V_{OUT1}, V_{OUT8}, and V_{OUT9} fluctuates, but the output voltage V_{OUT1} fluctuates less due to the load fluctuation than the output voltage V_{OUT8}. This is because the gm of the first error amplifier 22 is controlled by the current control circuit 200.

In the output voltage V_{OUT9} of the error amplifier circuit according to the second comparative technique, the gm is larger than that according to the first comparative technique, so that a fluctuation during the load fluctuation is suppressed more than in the output voltage V_{OUT8}. However, by increasing the gm, the output voltage V_{OUT9} becomes unstable during a steady state, causing oscillation. In contrast, in the error amplifier circuit 20 according to this embodiment, the gm is suppressed during the steady state, so that the output voltage V_{OUT1} is more stable during the steady state than the output voltage V_{OUT9}. Therefore, with the error amplifier circuit 20 according to the present embodiment, it is possible to suppress the fluctuation of the output voltage V_{OUT1} during the load fluctuation while stabilizing the output voltage V_{OUT1} during the steady state.

In addition, the inventors investigated frequency characteristics of the DC/DC converter 1 according to this embodiment and frequency characteristics of the DC/DC converter using the error amplifier circuit according to the first comparative technique, and found that there is no difference in the frequency characteristics between the two DC/DC converters. This result shows that the current control circuit 200 according to this embodiment does not affect the frequency characteristics of the error amplifier circuit 20. Therefore, the current control circuit 200 according to this embodiment may improve the response speed to the load fluctuation while maintaining the stability of the output voltage V_{OUT1}.

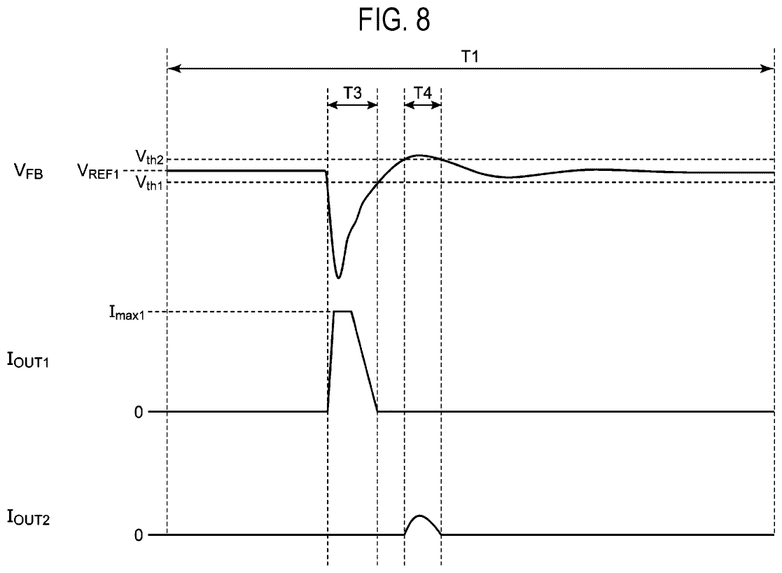

FIG. 8 is a diagram showing the first output current I_{OUT1} and the second output current I_{OUT2} during a period T1 shown in FIG. 7. The top of FIG. 8 shows the feedback voltage V_{FB} obtained by dividing the output voltage V_{OUT1}. As shown in FIG. 8, during a period T3 in a case of V_{FB}<Vₜₕ₁, a relationship of I_{OUT1}>0 is established. This increases the gm of the differential amplifier circuit 280 during the period T3, improving the response speed of the error amplifier circuit 20. As a result, a decrease in the feedback voltage V_{FB} (i.e., a decrease in the output voltage V_{OUT1} of the DC/DC converter 1) during the period T3 is suppressed.

In addition, in a period T4 in a case of V_{FB}>Vₜₕ₂, a relationship of I_{OUT2}>0 is established. This increases the gm of the differential amplifier circuit 280 during the period T4, improving the response speed of the error amplifier circuit 20. As a result, an increase in the feedback voltage V_{FB} (i.e., an increase in the output voltage V_{OUT1} of the DC/DC converter 1) during the period T4 is suppressed. In this way, the fluctuation in the feedback voltage V_{FB} (i.e., the fluctuation in the output voltage V_{OUT1} of the DC/DC converter 1) during the period T1 is suppressed.

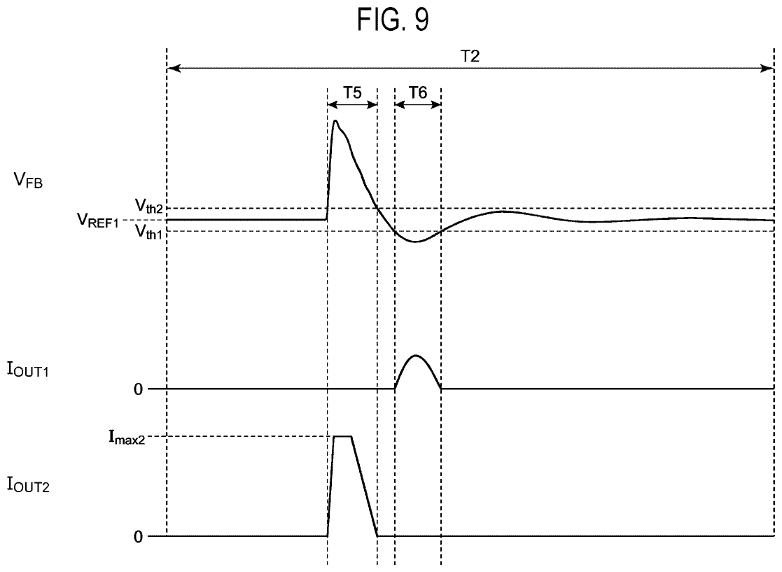

FIG. 9 is a diagram showing the first output current I_{OUT1} and the second output current I_{OUT2} during a period T2 shown in FIG. 7. As shown in FIG. 9, during a period T5 in a case of V_{FB}>Vₜₕ₂, a relationship of I_{OUT2}>0 is established, and during a period T6 in a case of V_{FB}<Vₜₕ₁, a relationship of I_{OUT1}>0 is established. As a result, in the same manner as in the period T1, the fluctuation of the feedback voltage V_{FB} (i.e., the fluctuation of the output voltage V_{OUT1} of the DC/DC converter 1) is suppressed during the period T2.

The DC/DC converter 1 according to this embodiment has been described above. In particular, the details of the first error amplifier 22 have been described. The first error amplifier 22 according to this embodiment is provided with the differential amplifier circuit 280 including the input differential pair 282 that operates according to the tail current Iₜₐᵢₗ, and the current control circuit 200 that controls the tail current Iₜₐᵢₗ of the differential amplifier circuit 280. The current control circuit 200 is configured to increase the tail current Iₜₐᵢₗ when the current supply condition is satisfied. The current supply condition is that the feedback voltage V_{FB} falls below the first threshold voltage Vₜₕ₁ which is equal to or lower than the reference voltage V_{REF1}, or that the feedback voltage V_{FB} exceeds the second threshold voltage Vₜₕ₂ which is equal to or higher than the reference voltage V_{REF1}.

With this configuration, when the feedback voltage V_{FB} falls below the first threshold voltage Vₜₕ₁ or exceeds the second threshold voltage Vₜₕ₂, the tail current Iₜₐᵢₗ of the differential amplifier circuit 280 becomes large. Thus, the gm of the first error amplifier 22 may be appropriately controlled according to the feedback voltage V_{FB}.

In addition, the first current control circuit 220 according to this embodiment is configured so that the first threshold voltage Vₜₕ₁ becomes a voltage lower by the first offset voltage V_{OFF1} than the reference voltage V_{REF1}. Further, the second current control circuit 260 according to this embodiment is configured so that the second threshold voltage Vₜₕ₂ becomes a voltage higher by the second offset voltage V_{OFF2} than the reference voltage V_{REF1}.

This prevents the gm of the first error amplifier 22 from increasing during the steady state. Thus, the gm of the first error amplifier 22 may be increased mainly when the load fluctuation (specifically, the fluctuation in the feedback voltage V_{FB}) occurs. As a result, the gm may be increased when the load fluctuation occurs, thereby suppressing the fluctuation in the output voltage V_{OUT1} while stabilizing the output voltage V_{OUT1} of the error amplifier circuit 20 during the steady state.

### Second Embodiment

In a second embodiment, a configuration of a current control circuit (specifically, a first current control circuit and a second current control circuit) of a first error amplifier is mainly different from that of the current control circuit 200 according to the first embodiment. The first error amplifier according to the second embodiment may have a configuration in which the current control circuit 200 of the first error amplifier 22 according to the first embodiment is replaced with the current control circuit according to the second embodiment. Further, a DC/DC converter according to the second embodiment may have substantially the same configuration as the DC/DC converter 1 according to the first embodiment, except for the first error amplifier.

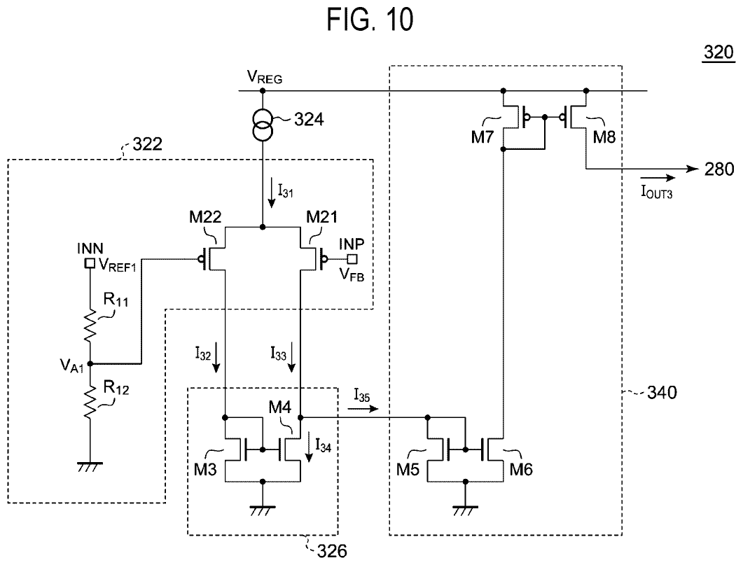

FIG. 10 is a circuit diagram of a first current control circuit 320 according to the second embodiment. The first current control circuit 320 according to the second embodiment is configured to generate a first output current I_{OUT3} that contributes to the tail current Iₜₐᵢₗ of the differential amplifier circuit 280 when the feedback voltage V_{FB} falls below a first threshold voltage Vₜₕ₅.

The first current control circuit 320 according to the second embodiment includes a first differential circuit 322, a current source 324, a first current mirror circuit 326, and a first current supply circuit 340. The current source 324, the first current mirror circuit 326, and the first current supply circuit 340 according to the second embodiment may have substantially the same configuration as the current source 224, the first current mirror circuit 226, and the first current supply circuit 240 of the first current control circuit 220 according to the first embodiment, respectively.

The first differential circuit 322 generates differential currents I₃₂ and I₃₃ according to a current I₃₁ supplied from the current source 324. The first differential circuit 322 according to the second embodiment includes transistors M21 and M22 and resistors R₁₁ and R₁₂. In the first differential circuit 322, the transistor M21 is a first transistor to which the feedback voltage V_{FB} is input, and the transistor M22 is a second transistor to which the first threshold voltage Vₜₕ₅ is input.

Each of the transistors M21 and M22 is configured as a P-channel MOS transistor. A gate of the transistor M21 is connected to a non-inverting input terminal INP. A source of the transistor M21 is connected to the current source 324 in common with a source of the transistor M22. A drain of the transistor M21 is connected to a drain of the transistor M4. A drain of the transistor M22 is connected to a drain of the transistor M3.

The resistors R11 and R12 are serially connected to each other. An inverting input terminal INN is connected to one end of the resistor R₁₁. A gate of the transistor M22 is connected between the resistors R₁₁ and R₁₂. A voltage V_{A1} obtained by dividing the reference voltage V_{REF1} is input to the gate of the transistor M22. Here, a relationship of V_{A1}=V_{REF1}×R₁₂/(R₁₁+R₁₂) is established. Therefore, a first offset voltage V_{OFF3} according to the second embodiment is V_{OFF3}=V_{REF1}−V_{A1}=V_{REF1}×R₁₁/(R₁₁+R₁₂). The first threshold voltage Vₜₕ₅ is Vₜₕ₅=V_{REF1}−V_{OFF3}=V_{A1}.

In a case of Vₜₕ₅≤V_{FB}, a relationship of I₃₂=I₃₃=I₃₄ is established. Here, the current I₃₃ is a drain current of the transistor M21, the current I₃₂ is a drain current of the transistor M22, and the current I₃₄ is a current flowing through the transistor M4. At this time, no current is supplied to the first current supply circuit 340 (I₃₅=0). The current I₃₅ is a drain current of the transistor M5.

When a load fluctuation occurs and V_{FB} drops so that a relationship of Vₜₕ₅>V_{FB} is established, a relationship of I₃₂<I₃₃ is established. At this time, since the current I₃₂ is copied by the first current mirror circuit 326, a relationship of I₃₂=I₃₄ is established, and the current I₃₅ (=I₃₃−I₃₄) is supplied to the first current supply circuit 340. The current I₃₄ is a current flowing through the transistor M4. The first output current I_{OUT3} corresponding to the current I₃₅ contributes to the tail current Iₜₐᵢₗ of the differential amplifier circuit 280.

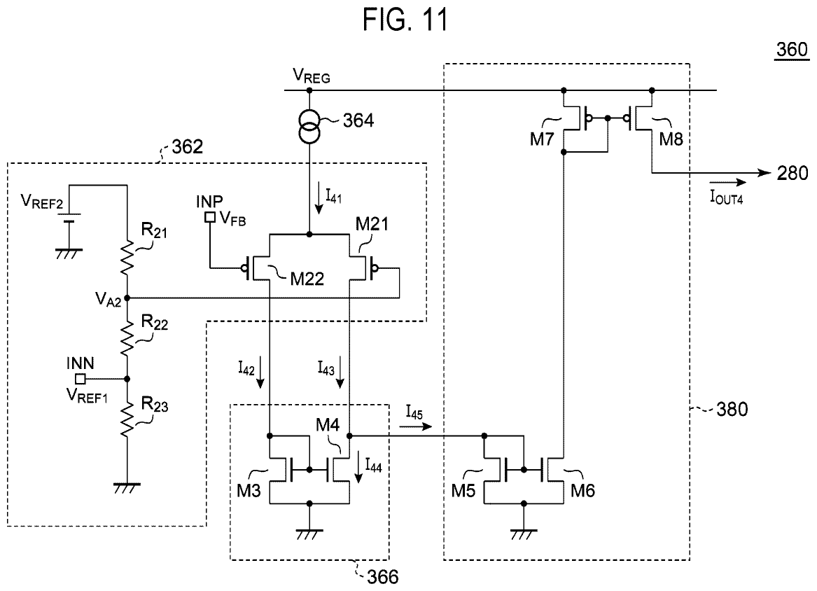

FIG. 11 is a circuit diagram of a second current control circuit 360 according to the second embodiment. The second current control circuit 360 according to the second embodiment is configured to generate a second output current I_{OUT4} that contributes to the tail current Iₜₐᵢ₁ of the differential amplifier circuit 280 when the feedback voltage V_{FB} exceeds a second threshold voltage Vₜₕ₆.

The second current control circuit 360 according to the second embodiment includes a second differential circuit 362, a current source 364, a fourth current mirror circuit 366, and a second current supply circuit 380. The current source 364, the fourth current mirror circuit 366, and the second current supply circuit 380 according to the second embodiment may have substantially the same configuration as the current source 224, the first current mirror circuit 226, and the first current supply circuit 240 of the first current control circuit 220 according to the first embodiment, respectively.

The second differential circuit 362 generates differential currents I₄₂ and I₄₃ according to a current I₄₁ supplied from the current source 364. The second differential circuit 362 according to the second embodiment includes transistors M21 and M22 and resistors R₂₁ to R₂₃. In the second differential circuit 362, the transistor M22 is a first transistor to which the feedback voltage V_{FB} is input, and the transistor M21 is a second transistor to which the second threshold voltage Vₜₕ₆ is input.

A source of the transistor M21 is connected to the current source 364 in common with a source of the transistor M22. A gate of the transistor M22 is connected to a non-inverting input terminal INP. The resistors R₂₁ to R₂₃ are serially connected to each other. An inverting input terminal INN is connected between the resistors R₂₂ and R₂₃. A gate of the transistor M21 is connected between the resistors R₂₁ and R₂₂. A voltage V_{A2} obtained by dividing a difference between the reference voltage V_{REF1} and a reference voltage V_{REF2} (>V_{REF1}) is input to a gate of the transistor M21. Here, a relationship of V_{A2}=(V_{REF2}−V_{REF1})×R₂₂/(R₂₁+R₂₂) is established. Therefore, a second offset voltage V_{OFF4} according to the second embodiment is V_{OFF4}=V_{A2}−V_{REF1}. The second threshold voltage Vₜₕ₆ is Vₜₕ₆=V_{REF1}+V_{OFF4}=V_{A2}.

In a case of Vₜₕ₆>V_{FB}, a relationship of I₄₂=I₄₃=I₄₄ is established. Here, the current I₄₃ is a drain current of the transistor M21, the current I₄₂ is a drain current of the transistor M22, and the current I₄₄ is a current flowing through the transistor M4. At this time, no current is supplied to the second current supply circuit 380 (I₄₅=0). The current I₄₅ is a drain current of the transistor M5.

When a load fluctuation occurs and V_{FB} rises so that a relationship of Vₜₕ₆<V_{FB} is established, a relationship of I₄₂<I₄₃ is established. At this time, since the current I₄₂ is copied by the fourth current mirror circuit 366, a relationship of I₄₂=I₄₄ is established, and the current I₄₅ (=I₄₃−I₄₄) is supplied to the second current supply circuit 380. The second output current I_{OUT4} corresponding to the current I₄₅ contributes to the tail current Iₜₐᵢₗ of the differential amplifier circuit 280.

Even if the first current control circuit 320 and the second current control circuit 360 are configured as described above, the tail current Iₜₐᵢₗ of the differential amplifier circuit 280 becomes large when the feedback voltage V_{FB} falls below the first threshold voltage Vₜₕ₅ or exceeds the second threshold voltage Vₜₕ₆. Thus, the gm of the first error amplifier according to the second embodiment may be appropriately controlled according to the feedback voltage V_{FB}.

### First Modification

In the above-described embodiments, an example has been described in which the offset voltage is generated by varying the number of multi of the differential pairs in the differential circuit of the current control circuit (the first embodiment), or by dividing the reference voltage using the resistors in the differential circuit of the current control circuit (the second embodiment). The method of generating the offset voltage is not limited thereto. For example, a differential circuit may be constituted with two transistors having different sizes as a differential pair with the same number of multi. By varying the size of the two transistors in this manner, it is possible to generate the offset voltage.

### Second Modification

In the first embodiment, an example has been described in which the number of transistors M1 is one and the number of transistors M2 is n in the first differential circuit 222 and the second differential circuit 262, making the number of multi different. However, the present disclosure is not limited thereto, and the number of transistors M1 may be m (m: an integer equal to or greater than 2). In this case, for example, by setting m<n, it is possible to generate an appropriate offset voltage.

### Third Modification

In the second embodiment, an example has been described in which the first threshold voltage Vₜₕ₁ and the second threshold voltage Vₜₕ₂ are generated using two voltage divider circuits in the first differential circuit 322 of the first current control circuit 320 and the second differential circuit 362 of the second current control circuit 360. However, the present disclosure is not limited thereto. Voltages that become these two threshold voltages may be generated using one voltage divider circuit.

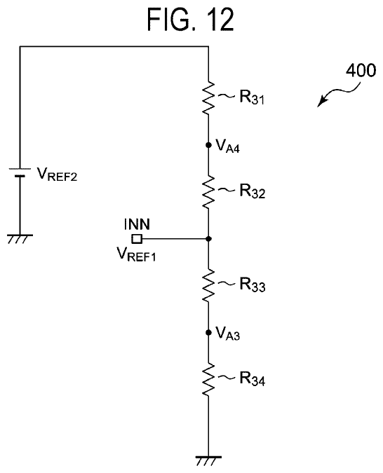

FIG. 12 is a diagram showing a voltage divider circuit 400 according to a third modification. The voltage divider circuit 400 according to the third modification includes resistors R₃₁ to R₃₄ serially connected to each other. A voltage V_{A3}, which is obtained by dividing the reference voltage V_{REF1}, is generated between the resistors R₃₃ and R₃₄. A relationship of V_{A3}=V_{REF1}×R₃₄/(R₃₃+R₃₄) is established. In addition, a voltage V_{A4}, which is obtained by dividing a difference between the reference voltage V_{REF1} and the reference voltage V_{REF2}, is generated between the resistors R₃₁ and R₃₂. Here, a relationship of V_{A4}=(V_{REF2}−V_{REF1})×R₃₂/(R₃₁+R₃₂) is established. By appropriately adjusting resistance values of the resistors R₃₁ to R₃₄, it is possible to use the voltage V_{A3} as the first threshold voltage and the voltage V_{A4} as the second threshold voltage.

### Applications

In the above-described embodiments, an example has been described in which the first error amplifier 22 or the error amplifier circuit 20 having the first error amplifier 22 is used in the DC/DC converter which is a switching regulator. However, the present disclosure is not limited thereto. The first error amplifier 22 or the error amplifier circuit 20 may be used in various DC/DC converters, for example, in a linear regulator such as an LDO.

### Supplement

The embodiments according to the present disclosure have been described using specific terms, but this description is merely an example to aid understanding and does not limit the scope of the present disclosure or the claims, and the scope of the present disclosure is defined by the claims. In addition to the embodiments, embodiments, examples, and modifications not described herein are also included in the scope of the present disclosure. It is also possible to combine one or more elements of the first embodiment with one or more elements of the second embodiment.

### Supplementary Notes

The technique disclosed in the present disclosure can be understood in one aspect as follows.

### Item 1

A transconductance amplifier that generates an output voltage by amplifying a difference between an input voltage and a reference voltage, includes:
a differential amplifier circuit including an input differential pair configured to receive the input voltage and the reference voltage and operate according to a tail current, and an output circuit provided as an active load of the input differential pair to generate the output voltage; and
a current control circuit configured to control the tail current,
wherein the current control circuit is configured to increase the tail current when a current supply condition is satisfied, and
wherein the current supply condition is that the input voltage falls below a first threshold voltage which is equal to or lower than the reference voltage, or that the input voltage exceeds a second threshold voltage which is equal to or higher than the reference voltage.

### (Item 2)

In the transconductance amplifier of Item 1 above, the current control circuit includes a differential circuit to which the input voltage and the reference voltage are input, a current mirror circuit provided as the active load of the differential circuit, and a current supply circuit provided as an active load of the current mirror circuit,
wherein the current mirror circuit supplies a current corresponding to a differential current of the differential circuit to the current supply circuit when the current supply condition is satisfied, and
wherein the current supply circuit contributes an output current, which corresponds to the current supplied from the current mirror circuit, to the tail current.

### (Item 3)

In the transconductance amplifier of Item 2 above, the differential circuit is configured so that the first threshold voltage is a voltage lower by a first offset voltage than the reference voltage, or the second threshold voltage is a voltage higher by a second offset voltage than the reference voltage.

### (Item 4)

In the transconductance amplifier of Item 3 above, the differential circuit includes one or more first transistors to which the input voltage is input, and one or more second transistors to which the reference voltage is input,
wherein the first transistor and the second transistor form a differential pair and are of a same type, and
wherein the number of one or more first transistors is different from the number of one or more second transistors.

### (Item 5)

In the transconductance amplifier of Item 3 above, the differential circuit includes a first transistor to which the input voltage is input, and a second transistor which forms a differential pair with the first transistor, and
wherein the second transistor receives the first threshold voltage or the second threshold voltage.

### (Item 6)

In the transconductance amplifier of any one of Items 2 to 6 above, when the current mirror circuit is a first current mirror circuit, the current supply circuit includes a second current mirror circuit provided as an active load of the first current mirror circuit, and a third current mirror circuit provided as an active load of the second current mirror circuit,
wherein, when the current supply condition is satisfied, the second current mirror circuit is provided to copy a current, which corresponds to a differential current of the differential circuit and is supplied from the first current mirror circuit, and
wherein the third current mirror circuit is provided to copy the current copied by the second current mirror circuit to generate the output current.

### (Item 7)

In the transconductance amplifier of Item 1 above, the current control circuit includes a first current control circuit and a second current control circuit,
wherein the first current control circuit is configured to increase the tail current when the input voltage falls below the first threshold voltage, and
wherein the second current control circuit is configured to increase the tail current when the input voltage exceeds the second threshold voltage.

### (Item 8)

In the transconductance amplifier of Item 7 above, the first current control circuit includes a first differential circuit to which the input voltage and the reference voltage are input, a first current mirror circuit provided as an active load of the first differential circuit, and a first current supply circuit provided as an active load of the first current mirror circuit,
wherein the second current control circuit includes a second differential circuit to which the input voltage and the reference voltage are input, a fourth current mirror circuit provided as an active load of the second differential circuit, and a second current supply circuit provided as an active load of the fourth current mirror circuit,
wherein the first current mirror circuit supplies a current corresponding to a differential current of the first differential circuit to the first current supply circuit when the input voltage falls below the first threshold voltage,
wherein the first current supply circuit contributes a first output current, which corresponds to the current supplied from the first current mirror circuit, to the tail current,
wherein the fourth current mirror circuit supplies a current corresponding to a differential current of the second differential circuit to the second current supply circuit when the input voltage exceeds the second threshold voltage, and
wherein the second current supply circuit contributes a second output current, which corresponds to the current supplied from the fourth current mirror circuit, to the tail current.

### (Item 9)

In the transconductance amplifier of Item 8 above, the first differential circuit is configured so that the first threshold voltage is a voltage lower by a first offset voltage than the reference voltage, and
wherein the second differential circuit is configured so that the second threshold voltage is a voltage higher by a second offset voltage than the reference voltage.

### (Item 10)

In the transconductance amplifier of any one of Items 1 to 9 above, the output circuit is configured as a cascode current mirror circuit.

### (Item 11)

A controller circuit for a DC/DC converter includes:
the transconductance amplifier of any one of Items 1 to 10 above,
wherein the input voltage is a feedback voltage of an output voltage of the DC/DC converter.

### (Item 12)

The controller circuit of Item 11 above is integrated on a single semiconductor chip.

### (Item 13)

A DC/DC converter includes the controller circuit of Item 11 or 12 above.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A transconductance amplifier that generates an output voltage by amplifying a difference between an input voltage and a reference voltage, comprising:
a differential amplifier circuit including an input differential pair configured to receive the input voltage and the reference voltage and operate according to a tail current, and an output circuit provided as an active load of the input differential pair to generate the output voltage; and
a current control circuit configured to control the tail current,
wherein the current control circuit is configured to increase the tail current when a current supply condition is satisfied, and
wherein the current supply condition is that the input voltage falls below a first threshold voltage which is equal to or lower than the reference voltage, or that the input voltage exceeds a second threshold voltage which is equal to or higher than the reference voltage.

2. The transconductance amplifier of claim 1, wherein the current control circuit includes a differential circuit to which the input voltage and the reference voltage are input, a current mirror circuit provided as the active load of the differential circuit, and a current supply circuit provided as an active load of the current mirror circuit,
wherein the current mirror circuit supplies a current corresponding to a differential current of the differential circuit to the current supply circuit when the current supply condition is satisfied, and
wherein the current supply circuit contributes an output current, which corresponds to the current supplied from the current mirror circuit, to the tail current.

3. The transconductance amplifier of claim 2, wherein the differential circuit is configured so that the first threshold voltage is a voltage lower by a first offset voltage than the reference voltage, or the second threshold voltage is a voltage higher by a second offset voltage than the reference voltage.

4. The transconductance amplifier of claim 3, wherein the differential circuit includes one or more first transistors to which the input voltage is input, and one or more second transistors to which the reference voltage is input,
wherein the first transistor and the second transistor form a differential pair and are of a same type, and
wherein the number of one or more first transistors is different from the number of one or more second transistors.

5. The transconductance amplifier of claim 3, wherein the differential circuit includes a first transistor to which the input voltage is input, and a second transistor which forms a differential pair with the first transistor, and
wherein the second transistor receives the first threshold voltage or the second threshold voltage.

6. The transconductance amplifier of claim 2, wherein, when the current mirror circuit is a first current mirror circuit, the current supply circuit includes a second current mirror circuit provided as an active load of the first current mirror circuit, and a third current mirror circuit provided as an active load of the second current mirror circuit,
wherein, when the current supply condition is satisfied, the second current mirror circuit is provided to copy a current, which corresponds to a differential current of the differential circuit and is supplied from the first current mirror circuit, and
wherein the third current mirror circuit is provided to copy the current copied by the second current mirror circuit to generate the output current.

7. The transconductance amplifier of claim 1, wherein the current control circuit includes a first current control circuit and a second current control circuit,
wherein the first current control circuit is configured to increase the tail current when the input voltage falls below the first threshold voltage, and
wherein the second current control circuit is configured to increase the tail current when the input voltage exceeds the second threshold voltage.

8. The transconductance amplifier of claim 7, wherein the first current control circuit includes a first differential circuit to which the input voltage and the reference voltage are input, a first current mirror circuit provided as an active load of the first differential circuit, and a first current supply circuit provided as an active load of the first current mirror circuit,
wherein the second current control circuit includes a second differential circuit to which the input voltage and the reference voltage are input, a fourth current mirror circuit provided as an active load of the second differential circuit, and a second current supply circuit provided as an active load of the fourth current mirror circuit,
wherein the first current mirror circuit supplies a current corresponding to a differential current of the first differential circuit to the first current supply circuit when the input voltage falls below the first threshold voltage,
wherein the first current supply circuit contributes a first output current, which corresponds to the current supplied from the first current mirror circuit, to the tail current,
wherein the fourth current mirror circuit supplies a current corresponding to a differential current of the second differential circuit to the second current supply circuit when the input voltage exceeds the second threshold voltage, and
wherein the second current supply circuit contributes a second output current, which corresponds to the current supplied from the fourth current mirror circuit, to the tail current.

9. The transconductance amplifier of claim 8, wherein the first differential circuit is configured so that the first threshold voltage is a voltage lower by a first offset voltage than the reference voltage, and
wherein the second differential circuit is configured so that the second threshold voltage is a voltage higher by a second offset voltage than the reference voltage.

10. The transconductance amplifier of claim 1, wherein the output circuit is configured as a cascode current mirror circuit.

11. A controller circuit for a DC/DC converter, comprising:
the transconductance amplifier of claim 1,
wherein the input voltage is a feedback voltage of an output voltage of the DC/DC converter.

12. The controller circuit of claim 11, which is integrated on a single semiconductor chip.

13. A DC/DC converter comprising:
the controller circuit of claim 11.
